(19) United States
(12) Patent Application Publication
(10) Pub. No.: US 2007/0152298 A1
(43) Pub. Date: Jul. 5, 2007

(54) INDUCTOR STRUCTURE OF A SEMICONDUCTOR DEVICE

(76) Inventor: Nam Joo Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/615,678

(22) Filed: Dec. 22, 2006

(30) Foreign Application Priority Data
Dec. 29, 2005 (KR) 10-2005-0134196

(51) Int. Cl. H01L 29/00

(52) U.S. Cl. 257/531

(57) ABSTRACT

Embodiments relate to and inductor structure of a semiconductor device and a manufacturing method of the same, that may be capable of reducing a parasitic capacitance occurring between an inductor metallic interconnection and a silicon substrate. Support insulating layer patterns may be formed on a top of the silicon substrate on which the interlayer dielectric layer is formed. Inductor metallic interconnections having relatively wide widths are formed on the support insulating layer patterns. When a top protective layer covering the inductor metallic interconnections is deposited, air layers are formed under the protruding parts of the inductor metallic interconnections. Because the air layer having a lower dielectric constant may exist between the inductor metallic interconnections and the silicon substrate, a parasitic capacitance may decrease and a self-resonance frequency may increase, and may extend an available frequency band.

The present application claims priority under 35 U.S.C. 119 and 35 U.S.C. 365 to Korean Patent Application No. 10-2005-0134196 (filed on Dec. 29, 2005), which is hereby incorporated by reference in its entirety.

### BACKGROUND

An inductor may be a component of a circuit for RF (radio frequency) communication, and may be used for RF components and analog components, which may be important in wireless communication devices. And inductor may be formed having a spiral structure. An inductor having a spiral structure may have a disadvantage of reducing a self-resonance frequency thereof due to a parasitic capacitance occurring between metallic interconnection of the inductor and a silicon substrate of a semiconductor device on which it may be formed.

In an inductor, a point where an inductance and a capacitance are interchanged as a frequency increases is referred to as a self-resonance frequency. An inductor may be typically be used in a frequency band lower than the self-resonance frequency. For an inductor having a spiral structure, as a device value becomes larger, a size of the device structure may become larger. This may cause parasitic components to increase, which may lower the self-resonance frequency. As a result, an available frequency band may be reduced.

FIG. 1A is an example diagram illustrating a structure of a related art inductor, and FIG. 1B is an example cross-sectional diagram taken along line A-A shown in FIG. 1A.

Referring to FIGS. 1A and 1B, interlayer dielectric layer 11 may be formed and planarized on a top of silicon substrate 10. Inductor metallic interconnection 12 of a spiral structure may be formed on the silicon substrate 10. Inductor metallic interconnection 12 may be connected to bottom metallic interconnection 12′ through a via (not shown). Top protective layer 13 may be formed on inductor metallic interconnection 12.

In such a spiral inductor structure, a self-resonance frequency may become smaller and an available frequency band may decrease due to a parasitic capacitance occurring between inductor metallic interconnection 12 and silicon substrate 10, as described above.

The parasitic capacitance occurring between an inductor metallic interconnection and a silicon substrate may present a problem due to a limitation on an available frequency band of the inductor.

### SUMMARY

Embodiments relate to a manufacturing technique of a semiconductor device. Embodiments relate to an inductor structure of a semiconductor device and a manufacturing method for the same, that may be capable of reducing a parasitic capacitance that may occur between an inductor metallic interconnection and a silicon substrate. According to embodiments, an available frequency band of the inductor may be expanded.

According to embodiments, an inductor structure of a semiconductor device may include an interlayer dielectric layer formed on a silicon substrate, support insulating layer patterns selectively formed on the interlayer dielectric layer, inductor metallic interconnections formed on the support insulating layer patterns and protruding from both sides of the support insulating layer patterns, a top protective layer covering the inductor metallic interconnections, and air layers formed under protruding parts of the inductor metallic interconnections.

According to embodiments, the top protective layer may include an oxide layer obtained through a plasma enhanced chemical vapor deposition process.

According to embodiments, a method of manufacturing a semiconductor device may include forming an interlayer dielectric layer on a top of a silicon substrate, forming a temporary insulating layer on a top of the interlayer dielectric layer, patterning the temporary insulating layer to selectively form openings, depositing a support insulating layer on an entire surface of the temporary insulating layer such that the openings are fully filled with the support insulating layer, planarizing the support insulating layer such that a top surface of the temporary insulating layer is exposed and support insulating layer patterns may be formed in the openings, depositing and patterning a metallic layer on an entire surface of the planarized support insulating layer to form inductor metallic interconnections in a manner that the inductor metallic interconnections protrude from both sides of the support insulating layer patterns, removing the temporary insulating layer, and depositing a top protective layer to cover the inductor metallic interconnections, wherein air layers are respectively formed under protruding parts of the inductor metallic interconnections in the step of depositing the top protective layer.

According to embodiments, the temporary insulating layer may include polyimide.

According to embodiments, the top protective layer may include an oxide layer obtained through a plasma enhanced chemical vapor deposition process.

### BRIEF DESCRIPTION OF THE DRAWINGS

FIG. 1A is an example diagram illustrating a related art inductor structure;

FIG. 1B is an example cross-sectional diagram taken along line A-A shown in FIG. 1A;

FIG. 2 is an example cross-sectional diagram illustrating an inductor structure according to embodiments; and

FIGS. 3A to 3G are example cross-sectional views illustrating an inductor and a procedure for manufacturing an inductor according to embodiments.

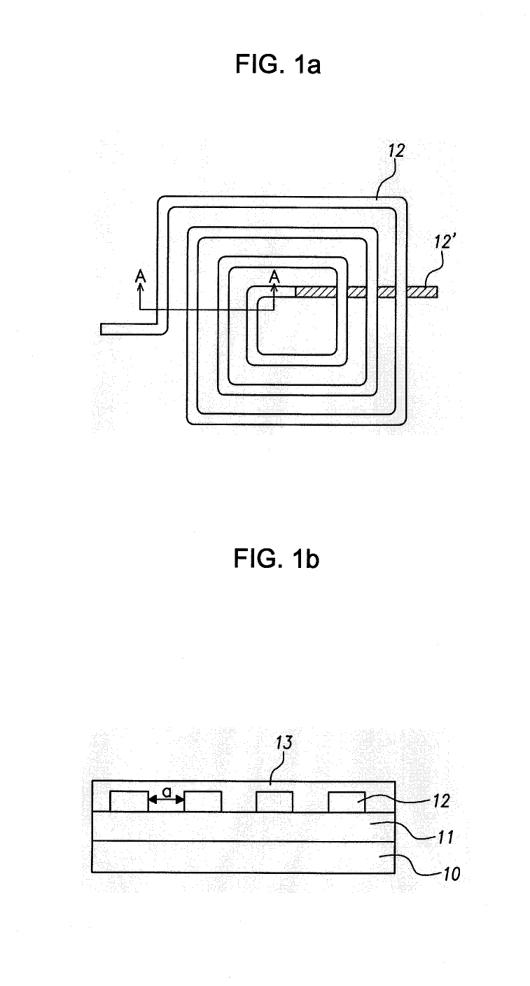

### DETAILED DESCRIPTION OF EMBODIMENTS

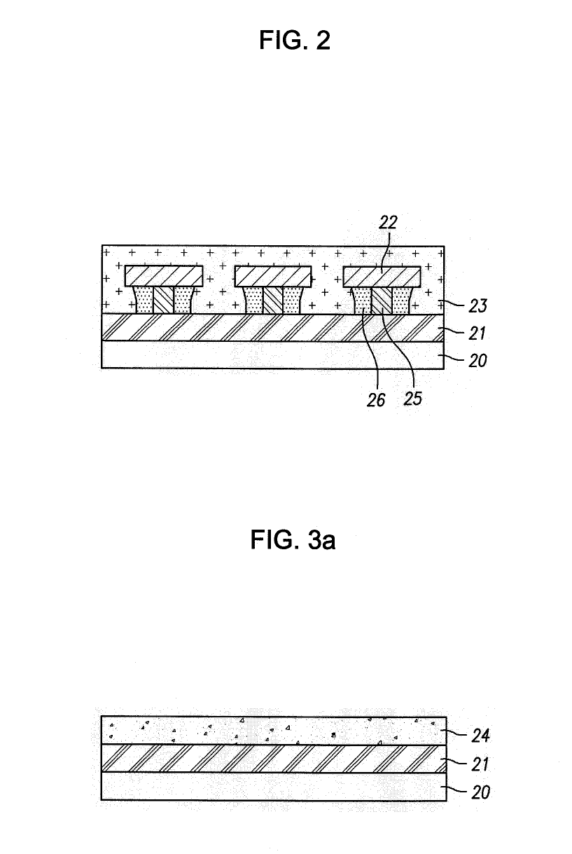

FIG. 2 is an example cross-sectional diagram illustrating an inductor structure according to embodiments.

Referring to FIG. 2, a plurality of support insulating layer patterns 25 may be selectively formed on a top of silicon substrate 20 on which interlayer dielectric layer 21 may be formed. Inductor metallic interconnections 22 may be respectively formed on support insulating layer patterns 25. A width of support insulating layer patterns 25 may be relatively narrower as compared to that of inductor metallic interconnections 22. Top protective layer 23, which may cover inductor metallic interconnections 22, may be formed on interlayer dielectric layer 21. In embodiments, inductor metallic interconnections 22, which may have any relatively wide width protruding from both sides of support insulating layer patterns 25. In addition, air layers 26 may be formed under the protruding parts of inductor metallic interconnections 22. In embodiments, inductor metallic interconnections 22 may protrude beyond an edge of air layers 26.

Interlayer dielectric layer 21 may be interposed between inductor metallic interconnections 22. Silicon substrate 20 may include an oxide-based layer having a high dielectric constant of approximately 3.0 or more. The same conditions may be similarly provided on top protective layer 23. Since air has a dielectric constant of at least 1.0, air layers 26 may be formed between inductor metallic interconnections 22 and silicon substrate 20. This may cause the parasitic capacitance to be reduced and may therefore cause the self-resonance frequency to increase. Accordingly, an available frequency band may be expanded.

Hereinafter, a manufacturing method of an inductor is described, according to embodiments.

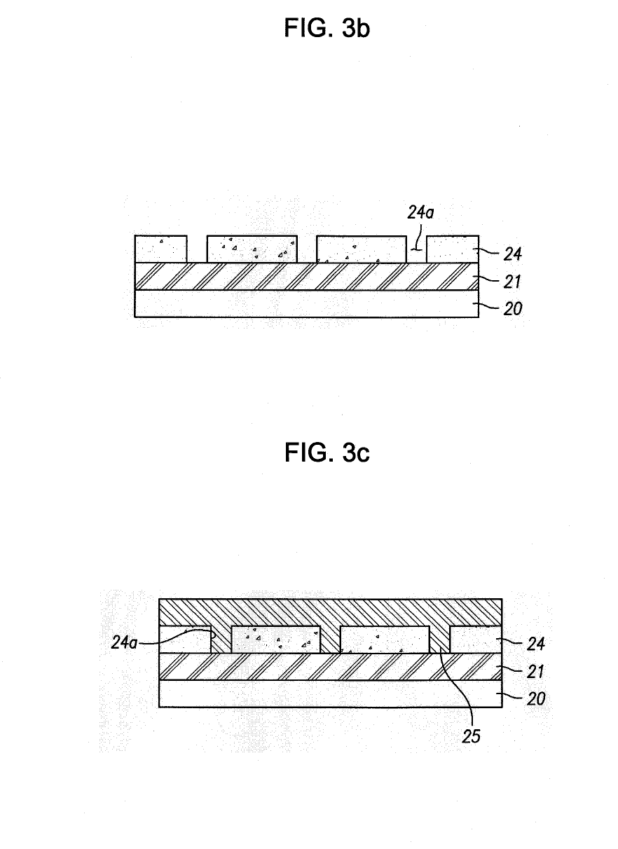

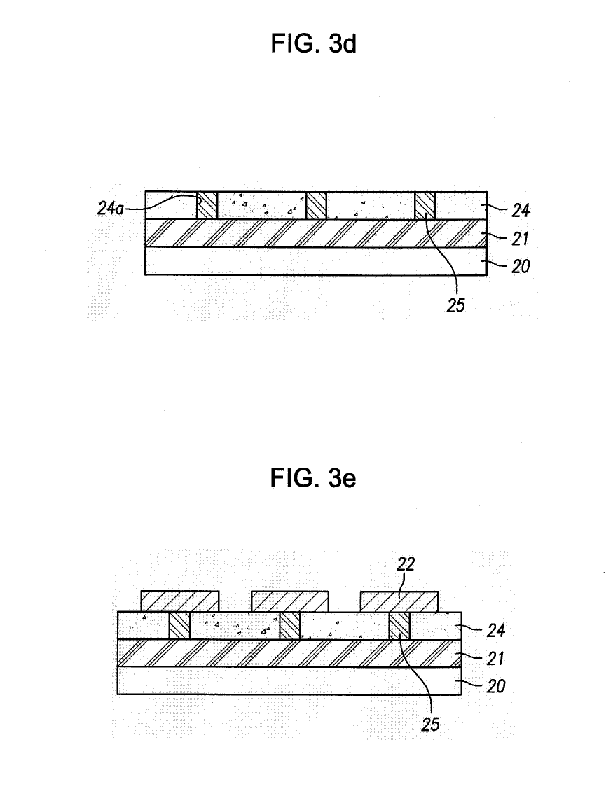

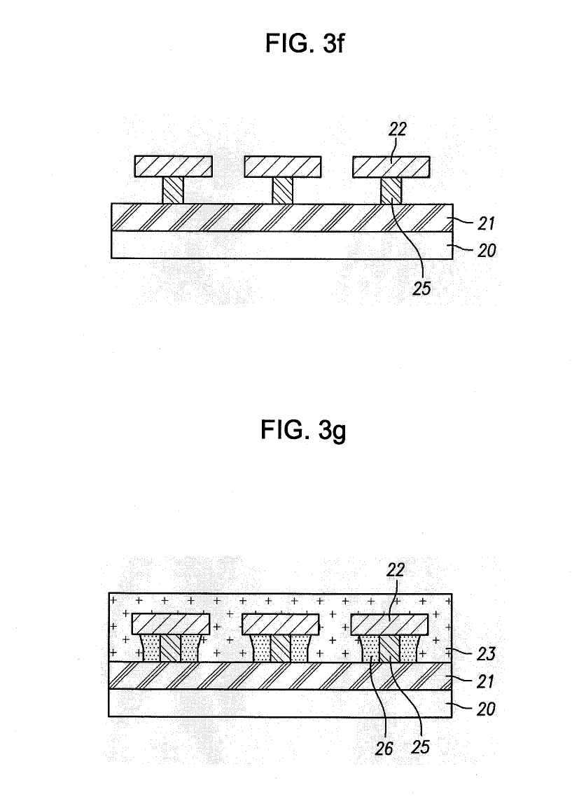

Referring to FIG. 3A, interlayer dielectric layer 21 may be formed and planarized on a top of silicon substrate 20. Then temporary insulating layer 24 may be formed on a top of interlayer dielectric layer 21. Temporary insulating layer 24 may be an insulating layer, which may be temporarily used in a process of manufacturing the inductor and may then be removed from the resultant structure. In embodiments, polyimide may be used as temporary insulating layer 24.

Referring to FIG. 3B, temporary insulating layer 24 may be patterned. In embodiments, openings 24A, which may be formed in portions removed by the patterning in temporary insulating layer 24, may correspond to centers of widths of inductor metallic layers 22, which may be formed later. Openings 24A may include a plurality of hole patterns or line patterns.

Referring to FIG. 3C, support insulating layer 25 may be deposited on a surface (for example, an entire surface) of temporary insulating layer 24. Support insulating layer 25 may be deposited on temporary insulating layer 24. Openings 24A of temporary insulating layer 24 may be fully filled with support insulating layer 25. In embodiments, an oxide layer or a nitride layer may be used as support insulating layer 25.

Referring to FIG. 3D, support insulating layer 25 may be planarized to expose a top surface of temporary insulating layer 24. Planarized support insulating layer 25 may remain only within openings 24A of temporary insulating layer 24, and may form the same patterns as openings 24A. In embodiments, a Chemical-Mechanical Policing (CMP) process may be used to planarize support insulating layer 25.

Referring to FIG. 3E, a metallic layer may be deposited and patterned on a surface (for example, the entire surface) of planarized support insulating layer patterns 25, and may form inductor metallic interconnections 22. According to embodiments, patterned inductor metallic interconnections 22 may be placed on support-insulating patterns 25, respectively. In embodiments, inductor metallic interconnections 22 may be patterned to have a width larger than that of corresponding support-insulating patterns 25 formed below inductor metallic interconnections 22. Accordingly, each inductor metallic interconnection 22 may have a shape protruding from both sides of support insulating layer patterns 25.

Referring to FIG. 3F, temporary insulating layer 24 may be completely removed. According to embodiments, a wet etching process may be used to remove temporary insulating layer 24, and temporary insulating layer 24 may be removed by introducing etchant between patterned inductor metallic interconnections 22.

Referring to FIG. 3G, top protective layer 23 may be deposited on the resultant structure such that inductor metallic interconnections 22 may be covered with top protective layer 23. In embodiments, an oxide layer obtained through a plasma enhanced-chemical vapor deposition (PE-CVD) process may be used as top protective layer 23. In embodiments, a lower space section of inductor metallic interconnections 22 may not be completely filled with top protective layer 23. Accordingly, air layers 26 maybe formed below protruding parts of inductor metallic interconnections 22.

According to embodiments, a support insulating layer may be formed with patterns having widths relatively narrower than widths of the inductor metallic interconnections on a top of the silicon substrate on which the interlayer dielectric layer may be formed, and may form relatively wide inductor metallic interconnections on the support insulating layer patterns. If the top protective layer covering the inductor metallic interconnections is deposited, air layers may be formed under the protruding parts of inductor metallic interconnections 22. Thus, because the air layers, which may have a low dielectric constant, may exist between the inductor metallic interconnections and the silicon substrate, parasitic capacitance may decrease, self-resonance frequency may increase, and an available frequency band may expand. Further, the inductor may provide high quality at specific frequency bands.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. An device comprising:
a plurality of support insulating layer patterns selectively formed over a semiconductor substrate;
inductor metallic interconnections formed over each of the support insulating layer patterns and configured to protrude over sides of corresponding support insulating layer patterns;
a cover layer formed over the inductor metallic interconnections and the semiconductor substrate; and
air layers formed under protruding parts of the inductor metallic interconnections.

2. The device of claim 1, further comprising an interlayer dielectric layer formed over the semiconductor substrate, wherein the plurality of support insulating patterns are formed over the interlayer dielectric layer.

3. The device of claim 1, wherein the air layers are formed between the semiconductor substrate and a bottom of the corresponding inductor metallic interconnections.

4. The device of claim 1, wherein the air layers are formed between a side of each support insulating layer and the cover layer.

5. The device of claim 1, wherein the cover layer comprises an oxide layer formed by a plasma enhanced chemical vapor deposition process.

6. A method comprising:
forming a plurality of support insulating layers over a silicon substrate;
forming a plurality of inductor metallic interconnections on corresponding support insulating layers such that a portion of the inductor metallic interconnections protrudes from sides of respective support insulating layers; and
depositing a cover layer over the inductor metallic interconnections and the silicon substrate such that air layers remain under protruding parts of the inductor metallic interconnections.

7. The method of claim 6, further comprising:
forming an interlayer dielectric layer over the silicon substrate;
forming a temporary insulating layer over the interlayer dielectric layer;
patterning the temporary insulating layer to selectively form openings;
depositing a support insulating layer over the temporary insulating layer such that the openings are filled with the support insulating layer;
depositing and patterning a metallic layer over the support insulating layer to form the inductor metallic interconnections such that a portion of the inductor metallic interconnections protrudes over sides of the support insulating layer within the openings;
removing the temporary insulating layer to form the plurality of support insulating layers; and
depositing the cover layer to cover the inductor metallic interconnections,
wherein the air layers are formed under the protruding parts of the inductor metallic interconnections by depositing the cover layer.

8. The method of claim 7, further comprising planarizing the support insulating layer such that a top surface of the temporary insulating layer is exposed and support insulating layer patterns are formed in the openings.

9. The method of claim 6, wherein the temporary insulating layer comprises polyimide.

10. The method of claim 6, wherein the cover layer comprises an oxide layer and is formed through a plasma enhanced chemical vapor deposition process.

11. A device comprising:
a support insulating layer formed over a semiconductor substrate; and
an inductor metallic connection formed over the supporting insulating layer, wherein a width of the inductor metallic connection is greater than a width of the support insulating layer.

12. The device of claim 11, wherein the support insulating layer comprises a first insulating layer and air pockets formed at sides of the first insulating layer.

13. The device of claim 12, wherein the air pockets are formed between a bottom of the inductor metallic connection and the semiconductor substrate.

14. The device of claim 13, further comprising an interlayer dielectric layer over the semiconductor substrate, wherein the support insulating layer is formed over the interlayer dielectric layer.

15. The device of claim 12, wherein the first insulating layer comprises at least one of an oxide layer and a nitride layer.

16. The device of claim 11, wherein the inductor metallic connection extends beyond outer edges of the support insulating layer.

17. The device of claim 11, further comprising a cover layer formed over the inductor metallic connection and the semiconductor substrate, wherein air pockets are formed between the support insulating layer and the cover layer below a portion of the inductor metallic connection.

18. The device of claim 17, wherein the support insulating layer comprises at least one of an oxide layer and a nitride layer.
